(19) United States
(12) Patent Application Publication
(10) Pub. No.: US 2006/0177600 A1
(43) Pub. Date: Aug. 10, 2006

(54) Inductive plasma system with sidewall magnet

(75) Inventors: Siqing Lu, San Jose, CA (US); Qiwei Liang, Fremont, CA (US); Canfeng Lai, Fremont, CA (US); Jason Bloking, Santa Clara, CA (US); Ellie Y. Yieh, San Jose, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/053,363

(22) Filed: Feb. 8, 2005

(51) Int. Cl. H05H 1/02; C23C 16/00; H05H 1/46

(52) U.S. Cl. 427/571; 427/575; 118/723 I; 118/715

(57) ABSTRACT

A substrate processing system has a housing that defines a process chamber. A substrate holder is disposed within the process chamber and configured to support a substrate within a substrate plane during substrate processing. A gas-delivery system is configured to introduce a gas into the process chamber. A pressure-control system maintains a selected pressure within the process chamber. A high-density-plasma generating system is operatively coupled with the process chamber. A magnetic confinement ring with magnetic dipoles is disposed circumferentially around a symmetry axis orthogonal to the substrate plane and provides a magnetic field with a net dipole moment substantially nonparallel with the substrate plane. A controller controls the gas-delivery system, the pressure-control system, and the high-density plasma system.

### BACKGROUND OF THE INVENTION

One of the primary steps in the fabrication of modern semiconductor devices is the formation of a film, such as a silicon oxide film, on a semiconductor substrate. Silicon oxide is widely used as an insulating layer in the manufacture of semiconductor devices. As is well known, a silicon oxide film can be deposited by a thermal chemical-vapor deposition (“CVD”) process or by a plasma-enhanced chemical-vapor deposition (“PECVD”) process. In a conventional thermal CVD process, reactive gases are supplied to a surface of the substrate, where heat-induced chemical reactions take place to produce a desired film. In a conventional plasma-deposition process, a controlled plasma is formed to decompose and/or energize reactive species to produce the desired film.

Semiconductor device geometries have decreased significantly in size since such devices were first introduced several decades ago, and continue to be reduced in size. This continuing reduction in the scale of device geometry has resulted in a dramatic increase in the density of circuit elements and interconnections formed in integrated circuits fabricated on a semiconductor substrate. One persistent challenge faced by semiconductor manufacturers in the design and fabrication of such densely packed integrated circuits is the desire to prevent spurious interactions between circuit elements, a goal that has required ongoing innovation as geometry scales continue to decrease.

Unwanted interactions are typically prevented by providing spaces between adjacent elements that are filled with an electrically insulative material to isolate the elements both physically and electrically. Such spaces are sometimes referred to herein as “gaps” or “trenches,” and the processes for filling such spaces are commonly referred to in the art as “gapfill” processes. The ability of a given process to produce a film that completely fills such gaps is thus often referred to as the “gapfill ability” of the process, with the film described as a “gapfill layer” or “gapfill film.” As circuit densities increase with smaller feature sizes, the widths of these gaps decrease, resulting in an increase in their aspect ratio, which is defined by the ratio of the gap's height to its depth. High-aspect-ratio gaps are difficult to fill completely using conventional CVD techniques, which tend to have relatively poor gapfill abilities. One family of electrically insulating films that is commonly used to fill gaps in intermetal dielectric (“IMD”) applications, premetal dielectric (“PMD”) applications, and shallow-trench-isolation (“STI”) applications, among others, is silicon oxide (sometimes also referred to as “silica glass” or “silicate glass”).

Some integrated circuit manufacturers have turned to the use of high-density plasma CVD (“HDP-CVD”) systems in depositing silicon oxide gapfill layers. Such systems form a plasma that has a density greater than about 10¹¹ ions/cm³, which is about two orders of magnitude greater than the plasma density provided by a standard capacitively coupled plasma CVD system. Inductively coupled plasma (“ICP”) systems are examples of HDP-CVD systems. One factor that allows films deposited by such HDP-CVD techniques to have improved gapfill characteristics is the occurrence of sputtering simultaneous with deposition of material. Sputtering is a mechanical process by which material is ejected by impact, and is promoted by the high ionic density of the plasma in HDP-CVD processes. The sputtering component of HDP deposition thus slows deposition on certain features, such as the corners of raised surfaces, thereby contributing to the increased gapfill ability.

Even with the use of HDP and ICP processes, a persistent challenge is to provide deposition processes that are uniform across a wafer. Nonuniformities lead to inconsistencies in device performance and may result from a number of different factors. The deposition characteristics at different points over a wafer result from a complex interplay of a number of different effects. For example, the way in which gas is introduced into the chamber, the level of power used to ionize precursor species, the use of electrical fields to direct ions, and the like, may ultimately affect the uniformity of deposition characteristics across a wafer. In addition, the way in which these effects are manifested may depend on the physical shape and size of the chamber, such as by providing different diffusive effects that affect the distribution of ions in the chamber.

There is accordingly a general need in the art for improved systems for improving deposition uniformity across a wafer in HDP and ICP processes.

### BRIEF SUMMARY OF THE INVENTION

Embodiments of the invention thus provide a substrate processing system that includes a magnetic confinement ring that may affect the plasma distribution to improve uniformity. A housing defines a process chamber for the system and a substrate holder is disposed within the process chamber and configured to support a substrate within a substrate plane during substrate processing. A gas-delivery system is configured to introduce a gas into the process chamber. A pressure-control system maintains a selected pressure within the process chamber. A high-density-plasma generating system is operatively coupled with the process chamber. A magnetic confinement ring having a plurality of magnetic dipoles is disposed circumferentially around a symmetry axis orthogonal to the substrate plane and provides a magnetic field with a net dipole moment substantially nonparallel with the substrate plane. A controller controls the gas-delivery system, the pressure-control system, and the high-density plasma system.

In some embodiments, the net dipole moment is substantially orthogonal to the substrate plane, which may result from each of the plurality of magnetic dipoles having a dipole moment that is substantially orthogonal to the substrate plane. In one embodiment, the plurality of magnetic dipoles comprise a plurality of permanent magnets. The magnetic confinement ring may also comprise a plurality of levels that are substantially parallel to the substrate plane, with the plurality of magnetic dipoles being disposed among the plurality of levels.

A number of different shapes and/or orientations may be provided for the magnetic confinement ring. For example, in one embodiment, the magnetic confinement ring comprises a holding structure made of magnetically conductive material, with the plurality of magnetic dipoles being held by the holding structure. In some instances, the magnetic confinement ring is substantially circular. In one embodiment, the magnetic confinement ring is disposed circumferentially around the housing. In another embodiment the magnetic confinement ring is disposed circumferentially around a side RF coil comprised by the high-density-plasma system. In still another embodiment, the magnetic confinement ring is integrated with a gas ring comprised by the gas-delivery system. The magnetic confinement ring may be substantially axisymmetric with the symmetry axis. In different embodiments, the magnetic confinement ring provides a field strength at an edge of a substrate disposed on the substrate less than about 2 gauss or less than about 1 gauss.

Embodiments of the invention also provide a method for depositing a film on a substrate disposed in a substrate plane within a substrate processing chamber. A process gas is flowed into the substrate processing chamber. A plasma having an ion density greater than 10¹¹ ions/cm³ is formed inductively from the process gas. A magnetic field is generated with a magnetic confinement ring having a plurality of magnetic dipoles disposed circumferentially around a symmetry axis orthogonal to the substrate plane. The magnetic field has a net dipole moment substantially nonparallel with the substrate plane. The film is deposited over the substrate with the plasma in a process that has simultaneous deposition and sputtering components.

In some cases, the substrate has a trench formed between adjacent raised surfaces. When the film is deposited over the substrate, it is deposited within the trench. The process gas may comprise a silicon source, an oxygen source, and a fluent gas. The methods may be performed with the substrate processing systems described above, including various alternative embodiments that have been identified.

A further understanding of the nature and advantages of the present invention may be realized by reference to the remaining portions of the specification and the drawings.

### BRIEF DESCRIPTION OF THE DRAWINGS

FIG. 1 is a simplified cross-sectional view of an exemplary ICP reactor system according to an embodiment of the invention;

FIG. 2 shows experimental and simulation results to illustrate the cause and effect of deposition nonuniformities in an ICP chamber;

FIGS. 3A-3C show a structure for a magnetic confinement ring used with an ICP chamber in embodiments of the invention;

FIGS. 4A-4C are schematic illustrations of different configurations that may be used to provide an ICP reactor system with a magnetic confinement ring in different embodiments;

FIG. 5 is a graphical illustration of a radial dependence of magnetic-field strength provided by the magnetic confinement ring of FIG. 3A in one embodiment; and

FIG. 6 is a flow diagram illustrating a method for depositing a film into gaps on a wafer using an ICP reactor system with a magnetic confinement ring.

### DETAILED DESCRIPTION OF THE INVENTION

1. Overview

Embodiments of the invention provide an ICP reactor that uses a magnetic field generated by a magnetic confinement ring to control the distribution of ionic species within the chamber. When the inventors were initially confronted with the problem of improving deposition uniformity, they began by considering a number of different sources for nonuniformities and undertook a variety of studies to understand how these sources contributed to the resultant nonuniformity. These studies included both simulation and experimental studies. In particular, three principal classes of factors were identified as bearing on uniformity characteristics: plasma characteristics, chamber flow distributions, and thermal effects.

For example, in gapfill applications, better overall gapfill is achieved with higher ion densities in the plasma. Similarly, improved center-to-edge uniformity across a wafer is achieved when the ion distribution in the chamber has better uniformity. One reason that many ICP and HDP chambers have both top and side RF coils has been to try to improve the uniformity of the ion distribution in the chamber. It is generally expected that the effect of a top coil is to produce a plasma density that is greater at the center of the wafer and lower at the edge of the wafer, and that the opposite effect should result from side coils. While the inventors did confirm that the ion uniformity was generally improved with greater side-coil power, they also found that even the use of only side-coil power tends to produce a nonuniform ion density peaked over the center of the wafer, but much less strongly than seen with top-coil power. This was identified as a consequence of diffusive effects, particularly am-bipolar diffusion.

The chamber flow distributions are generally dictated by the location of gas nozzles that introduce precursor into the chamber, and by the presence of structure within the chamber that may affect flow characteristics, such as baffle structures and the like. In addition, the rates at which precursor gases are provided to the chamber through the nozzles affect the flow characteristics. One measure in which the variation in flow characteristics is evident is in the variation of a deposition/sputter ratio across the wafer. The deposition/sputter ratio is one of several commonly used measures that quantify high-density plasma processes according to the relative contributions of the simultaneous deposition and sputtering components of the process. Characterization of the plasma as a “high-density” plasma means that the average ion density of the plasma is greater than about 10¹¹ ions/cm³, with the deposition/sputter ratio being defined as:

$$\frac{D}{S} ≡ \frac{( net deposition rate ) + ( blanket sputtering rate )}{( blanket sputtering rate )} .$$

The deposition/sputter rate increases with increased deposition and decreases with increased sputtering. As used in the definition of D/S, the “net deposition rate” refers to the deposition rate that is measured when deposition and sputtering are occurring simultaneously. The “blanket sputter rate” is the sputter rate measured when the process recipe is run without deposition gases; the pressure within the process chamber is adjusted to the pressure during deposition and the sputter rate measured on a blanket thermal oxide.

Other equivalent measures may be used to quantify the relative deposition and sputtering contributions of high-density plasma processes, as is known to those of skill in the art. A common alternative ratio is the “etching/deposition ratio,”

$$\frac{E}{D} ≡ \frac{( source \text{-} only deposition rate ) - ( net deposition rate )}{( source \text{-} only deposition rate )} ,$$

which increases with increased sputtering and decreases with increased deposition. As used in the definition of E/D, the “net deposition rate” again refers to the deposition rate measured when deposition and sputtering are occurring simultaneously. The “source-only deposition rate,” however, refers to the deposition rate that is measured when the process recipe is run with no sputtering. Embodiments of the invention are described herein in terms of D/S ratios. While D/S and E/D are not precise reciprocals, they are inversely related and conversion between them will be understood to those of skill in the art.

The studies performed by the inventors confirmed that jet effects as gas is provided from nozzles affects the variation in deposition/sputter ratio characteristics, with more diffusive jets providing better overall uniformity. In addition, shorter nozzles were found to provide better overall gapfill uniformity than were longer nozzles, which produced greater variation in gapfill across the wafer.

Thermal effects influence uniformity because they are directly related to the kinetic energy of the ionic species and therefore affect both the deposition/sputter ratio of the plasma and affect diffusive characteristics of the plasma. The temperature within the chamber is often chosen to be consistent with performance criteria defined by the chemical properties of the precursor gases used for the process so that different processes may have different uniformity concerns. For instance, gapfill processes are frequently used for the deposition of silicon oxide by providing precursor flows of monosilane SiH₄ and molecular oxygen O₂ to the chamber with a fluent gas. Depending on the physical structures of the gaps to be filled, including their separations, aspect ratios, and the like, different fluent gases may be preferred. For instance, some processes use a relatively heavy gas like Ar while other processes use lighter gases such as He and/or H₂, as described in commonly assigned U.S. patent application Ser. No. 10/137,132, entitled “METHOD FOR HIGH ASPECT RATIO HDP CVD GAPFILL,” filed Apr. 30, 2002 by Zhong Qiang Hua et al. and commonly assigned U.S. patent application Ser. No. 10/350,445, entitled “HYDROGEN ASSISTED HDP-CVD DEPOSITION PROCESS FOR AGGRESSIVE GAP-FILL TECHNOLOGY,” filed Jan. 23, 2003 by Bikram Kapoor et al., the entire disclosures of both of which are herein incorporated by reference for all purposes. Processes that use lighter fluent gases like H₂ tend to use higher chamber temperatures, leading to different kinetic characteristics of the plasma ions and affecting the wafer uniformity of the process

The inclusion of the magnetic confinement ring according to embodiments of the invention addresses these various effects for specific processes by using magnetic effects to further concentrate ions near the wafer edge and thereby enhance uniformity characteristics. The result is to control ion directionality and create a generally more diffusive flow pattern. As discussed below, this permits a number of beneficial effects, including allowing overall gapfill to be extended to more processes, improving center-to-edge gapfill uniformity, and reducing the variation in deposition/sputter ratios of the plasma process.

2. Exemplary ICP Chamber

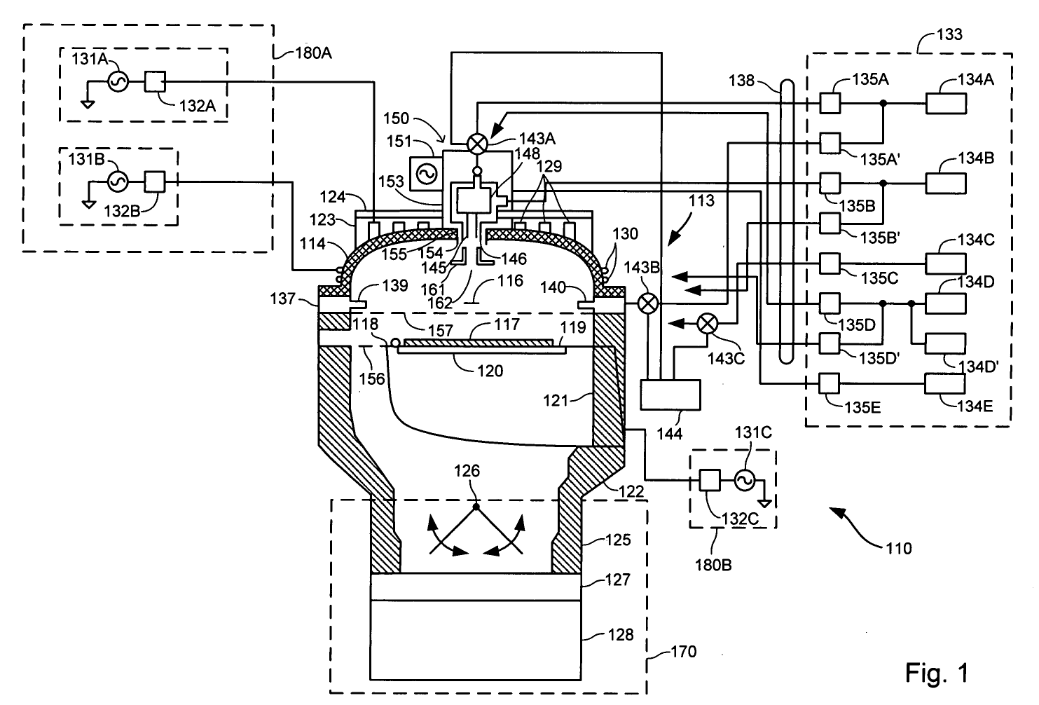

The inventors have implemented embodiments of the invention with the ULTIMA™ system manufactured by APPLIED MATERIALS, INC., of Santa Clara, Calif., a general description of which is provided in commonly assigned U.S. Pat. No. 6,170,428, “SYMMETRIC TUNABLE INDUCTIVELY COUPLED HDP-CVD REACTOR,” filed Jul. 15, 1996 by Fred C. Redeker, Farhad Moghadam, Hirogi Hanawa, Tetsuya Ishikawa, Dan Maydan, Shijian Li, Brian Lue, Robert Steger, Yaxin Wang, Manus Wong and Ashok Sinha, the entire disclosure of which is incorporated herein by reference. An overview of the ICP reactor is provided in connection with FIG. 1 below. The ICP reactor is part of an HDP-CVD system 110 that includes a chamber 113, a vacuum system 170, a source plasma system 180A, a bias plasma system 180B, a gas delivery system 133, and a remote plasma cleaning system 150. The upper portion of chamber 113 includes a dome 114, which is made of a ceramic dielectric material, such as aluminum oxide or aluminum nitride. Dome 114 defines an upper boundary of a plasma processing region 116. Plasma processing region 116 is bounded on the bottom by the upper surface of a substrate 117 and a substrate support member 118.

A heater plate 123 and a cold plate 124 surmount, and are thermally coupled to, dome 114. Heater plate 123 and cold plate 124 allow control of the dome temperature to within about ±10° C. over a range of about 100° C. to 200° C. This allows optimizing the dome temperature for the various processes. For example, it may be desirable to maintain the dome at a higher temperature for cleaning or etching processes than for deposition processes. Accurate control of the dome temperature also reduces the flake or particle counts in the chamber and improves adhesion between the deposited layer and the substrate.

The lower portion of chamber 113 includes a body member 122, which joins the chamber to the vacuum system. A base portion 121 of substrate support member 118 is mounted on, and forms a continuous inner surface with, body member 122. Substrates are transferred into and out of chamber 113 by a robot blade (not shown) through an insertion/removal opening (not shown) in the side of chamber 113. Lift pins (not shown) are raised and then lowered under the control of a motor (also not shown) to move the substrate from the robot blade at an upper loading position 157 to a lower processing position 156 in which the substrate is placed on a substrate receiving portion 119 of substrate support member 118. Substrate receiving portion 119 includes an electrostatic chuck 120 that secures the substrate to substrate support member 118 during substrate processing. In a preferred embodiment, substrate support member 118 is made from an aluminum oxide or aluminum ceramic material.

Vacuum system 170 includes throttle body 125, which houses twin-blade throttle valve 126 and is attached to gate valve 127 and small-molecule-enhanced turbomolecular pump 128. As described in detail below, the turbomolecular pump 128 has the modified performance characteristics making it suitable for efficient exhaustion of low-mass molecular species. It should be noted that throttle body 125 offers minimum obstruction to gas flow, and allows symmetric pumping. Gate valve 127 can isolate pump 128 from throttle body 125, and can also control chamber pressure by restricting the exhaust flow capacity when throttle valve 126 is fully open. The arrangement of the throttle valve, gate valve, and small-molecule-enhanced turbomolecular pump allow accurate and stable control of chamber pressures from between about 2 millitorr to about 2 torr.

The source plasma system 180A includes a top coil 129 and side coil 130, mounted on dome 114. A symmetrical ground shield (not shown) reduces electrical coupling between the coils. Top coil 129 is powered by top source RF (SRF) generator 131A, whereas side coil 130 is powered by side SRF generator 131B, allowing independent power levels and frequencies of operation for each coil. This dual coil system allows control of the radial ion density in chamber 113, thereby improving plasma uniformity. Side coil 130 and top coil 129 are typically inductively driven, which does not require a complimentary electrode. In a specific embodiment, the top source RF generator 131A provides up to 2,500 watts of RF power at nominally 2 MHz and the side source RF generator 131B provides up to 5,000 watts of RF power at nominally 2 MHz. The operating frequencies of the top and side RF generators may be offset from the nominal operating frequency (e.g. to 1.7-1.9 MHz and 1.9-2.1 MHz, respectively) to improve plasma-generation efficiency.

A bias plasma system 180B includes a bias RF (“BRF”) generator 131C and a bias matching network 132C. The bias plasma system 180B capacitively couples substrate portion 117 to body member 122, which act as complimentary electrodes. The bias plasma system 180B serves to enhance the transport of plasma species (e.g., ions) created by the source plasma system 180A to the surface of the substrate. In a specific embodiment, bias RF generator provides up to 5,000 watts of RF power at 13.56 MHz.

RF generators 131A and 131B include digitally controlled synthesizers and operate over a frequency range between about 1.8 to about 2.1 MHz. Each generator includes an RF control circuit (not shown) that measures reflected power from the chamber and coil back to the generator and adjusts the frequency of operation to obtain the lowest reflected power, as understood by a person of ordinary skill in the art. RF generators are typically designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

Matching networks 132A and 132B match the output impedance of generators 131A and 131B with their respective coils 129 and 130. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of a layer.

A gas delivery system 133 provides gases from several sources, 134A-134E chamber for processing the substrate via gas delivery lines 138 (only some of which are shown). As would be understood by a person of skill in the art, the actual sources used for sources 134A-134E and the actual connection of delivery lines 138 to chamber 113 varies depending on the deposition and cleaning processes executed within chamber 113. Gases are introduced into chamber 113 through a gas ring 137 and/or a top nozzle 145. A plurality of source gas nozzles 139 (only one of which is shown in the illustration) provide a uniform flow of gas over the substrate. Nozzle length and nozzle angle may be changed to allow tailoring of the uniformity profile and gas utilization efficiency for a particular process within an individual chamber. In one embodiment, twelve source gas nozzles made from an aluminum oxide ceramic are provided.

In addition, a plurality of oxidizer gas nozzles 140 (only one of which is shown), which in a preferred embodiment are co-planar with and shorter than source gas nozzles 139. In some embodiments it is desirable not to mix source gases and oxidizer gases before injecting the gases into chamber 113. In other embodiments, oxidizer gas and source gas may be mixed prior to injecting the gases into chamber 113. In one embodiment, third, fourth, and fifth gas sources, 134C, 134D, and 134D′, and third and fourth gas flow controllers, 135C and 135D′, provide gas to body plenum via gas delivery lines 138. Additional valves, such as 143B (other valves not shown), may shut off gas from the flow controllers to the chamber.

In embodiments where flammable, toxic, or corrosive gases are used, it may be desirable to eliminate gas remaining in the gas delivery lines after a deposition. This may be accomplished using a 3-way valve, such as valve 143B, to isolate chamber 113 from the delivery lines and to vent the delivery lines to vacuum foreline 144, for example. As shown in FIG. 1, other similar valves, such as 143A and 143C, may be incorporated on other gas delivery lines. Such three-way valves may be placed as close to chamber 113 as practical, to minimize the volume of the unvented gas delivery line (between the three-way valve and the chamber). Additionally, two-way (on-off) valves (not shown) may be placed between a mass flow controller (“MFC”) and the chamber or between a gas source and an MFC.

The chamber 113 also has top nozzle 145 and top vent 146. Top nozzle 145 and top vent 146 allow independent control of top and side flows of the gases, which improves film uniformity and allows fine adjustment of the film's deposition and doping parameters. Top vent 146 is an annular opening around top nozzle 145. In one embodiment, first gas source 134A supplies source gas nozzles 139 and top nozzle 145. Source nozzle MFC 135A′ controls the amount of gas delivered to source gas nozzles 139 and top nozzle MFC 135A controls the amount of gas delivered to top gas nozzle 145. Similarly, two MFCs 135B and 135B′ may be used to control the flow of oxygen to both top vent 146 and oxidizer gas nozzles 140 from a single source of oxygen, such as source 134B. In some embodiments, oxygen is not supplied to the chamber from any side nozzles. The gases supplied to top nozzle 145 and top vent 146 may be kept separate prior to flowing the gases into chamber 113, or the gases may be mixed in top plenum 148 before they flow into chamber 113. Separate sources of the same gas may be used to supply various portions of the chamber.

A remote microwave-generated plasma cleaning system 150 is provided to periodically clean deposition residues from chamber components. The cleaning system includes a remote microwave generator 151 that creates a plasma from a cleaning gas source 134E (e.g., molecular fluorine, nitrogen trifluoride, other fluorocarbons or equivalents) in reactor cavity 153. The reactive species resulting from this plasma are conveyed to chamber 113 through cleaning gas feed port 154 via applicator tube 155. The materials used to contain the cleaning plasma (e.g., cavity 153 and applicator tube 155) must be resistant to attack by the plasma. The distance between reactor cavity 153 and feed port 154 should be kept as short as practical, since the concentration of desirable plasma species may decline with distance from reactor cavity 153. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as electrostatic chuck 120, do not need to be covered with a dummy wafer or otherwise protected, as may be required with an in situ plasma cleaning process. In FIG. 1, the plasma-cleaning system 150 is shown disposed above the chamber 113, although other positions may alternatively be used.

A baffle 161 may be provided proximate the top nozzle to direct flows of source gases supplied through the top nozzle into the chamber and to direct flows of remotely generated plasma. Source gases provided through top nozzle 145 are directed through a central passage 162 into the chamber, while remotely generated plasma species provided through the cleaning gas feed port 154 are directed to the sides of the chamber 113 by the baffle 161.

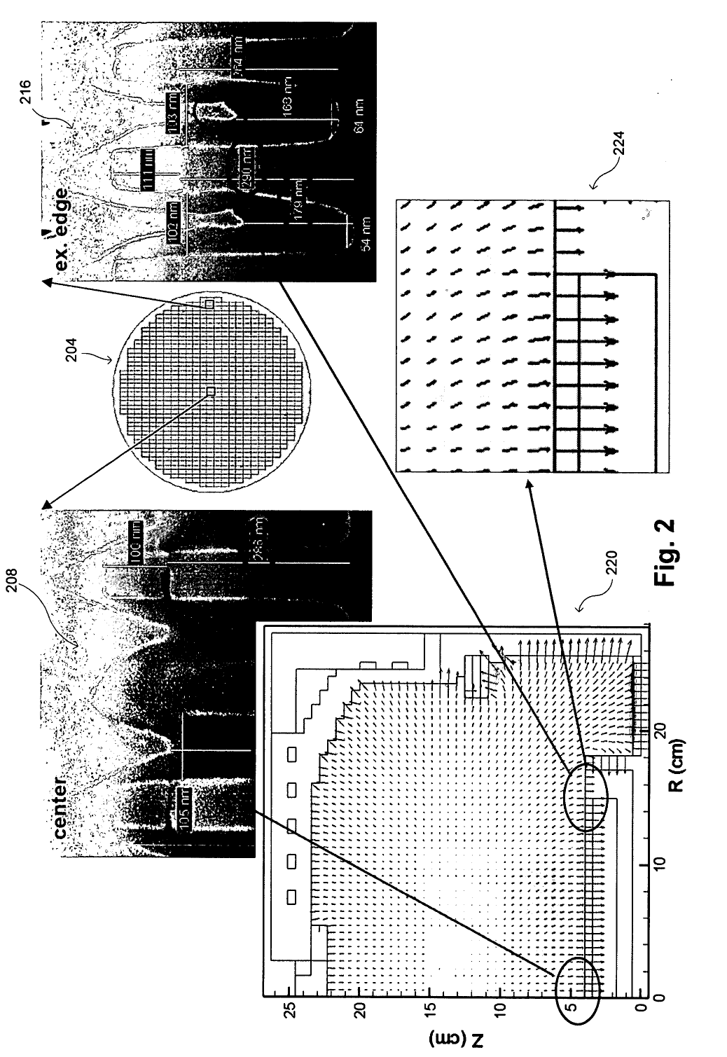

Simulation and experimental results that illustrate the origin and effect of nonuniformities across the wafer are summarized in FIG. 2. This drawing shows the results of simulations of ion directionality and provides SEM images of material deposited in gaps on a wafer 204. SEM image 208 shows gapfill near the center of the wafer 204 and may be compared with SEM image 216 showing gapfill near the edge of the wafer. It is evident from these images that better bottom-up gapfill characteristics are achieved near the center of the wafer 204 than near its edge. Furthermore, the material is deposited in a more uniform downwards direction near the center of the wafer, as is evident from the tilting of the deposited structures in SEM image 216 taken near the wafer edge.

This tilting is a consequence of the directionality of precursor ions, which is shown in the simulation results 220. Near the center in the wafer, the ions encounter the gap while traveling in a substantially downwards direction, but near the edge of the wafer, the ion direction vectors deviate from substantial orthogonality to the wafer surface. This is more evident with the enlarged version of the simulation results shown in panel 224.

3. Magnetic Confinement Ring

Embodiments of the invention affect the directionality of the ions near the wafer edge by providing a magnetic field that has a net dipole moment with a direction substantially nonparallel with a plane of the wafer. In some embodiments, the net dipole moment is substantially orthogonal to the plane of the wafer. In specific embodiments, the magnetic field is a superposition of magnetic fields generated by a plurality of magnetic dipoles having dipole moments substantially nonparallel with the plane of the wafer and, in some instances, being substantially orthogonal to the plane of the wafer. The plurality of magnetic dipoles may be distributed in a ring distributed circumferentially about the plasma chamber, thereby providing a field stronger near an edge of the wafer than near a center of the wafer.

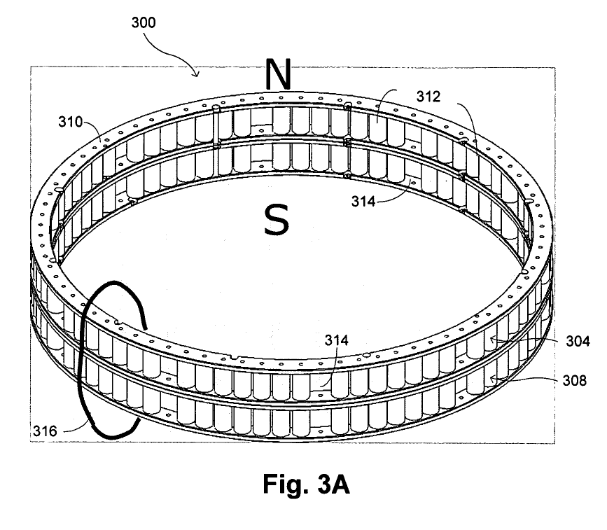

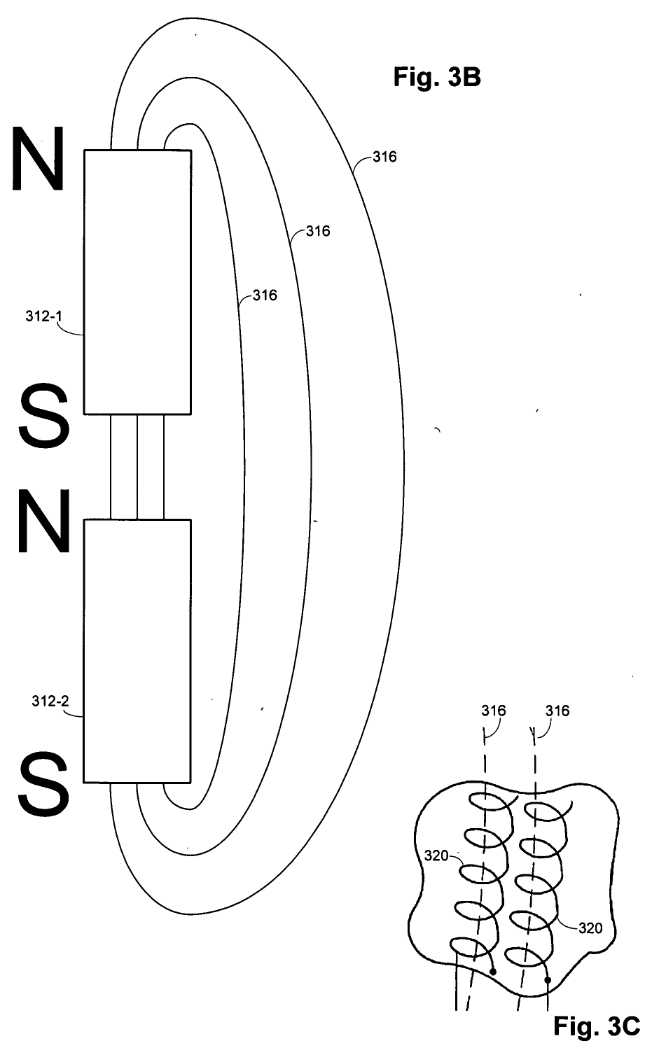

One configuration that provides a magnetic field having these characteristics is shown in FIG. 3A. The magnetic field is generated by a magnetic confinement ring 300 that comprises a plurality of magnetic dipoles. In this embodiment, the magnetic dipoles are provided by permanent magnets 312 held within a holding structure 310, but may alternatively be provided with electromagnets or other magnetic structures. The ring within which the magnetic dipoles are distributed is substantially circular, but this is not a requirement of the invention and the ring may have some ellipticity in alternative embodiments. While an elliptical configuration may be useful in embodiments where the deposition on the wafer lacks rotational symmetry, such as may result from the distribution of gas nozzles around the chamber, it is generally expected that such an elliptical configuration will have a small eccentricity. It is also possible in some embodiments for the magnetic dipoles to be distributed over multiple levels orthogonal to the plane of the wafer. The ring 300 in FIG. 3A has two such levels 304 and 308, but other embodiments may use a single level, may use three levels, or may use a higher number of levels. The use of multiple levels may advantageously increase the dipole moment even when magnets having a smaller dipole moment are used.

The magnetic field generated by the ring 304 is illustrated in FIG. 3B for a single pair of aligned permanent magnets 312. When multiple levels of magnets are used, each magnet is aligned with a similar polarity so that if magnet 312-1 has a top north pole and a bottom south pole, corresponding magnet 312-2 on another level also has a top north pole and a bottom south pole. The up/down character of the field lines 316 is a consequence of having the magnet moments aligned substantially orthogonally to the plane of the wafer. Each set of magnets around the ring produces a similar field structure, as shown also in FIG. 3A by magnetic field line 316. The total magnetic field is a superposition of such fields around the ring, and it may therefore be visualized as a rotation of the field shown in FIG. 3B about an axis that extends through the center of the ring. It is evident that the field is thus strongest at the ring and decreases in strength towards the center of the ring, thereby providing a field stronger at the edge of the wafer than at the center when disposed circumferentially about a plasma chamber.

Because the plasma species are charged, they will follow helical gyromagnetic paths about the field lines, as illustrated in FIG. 3C. The gyromagnetic radius of the helical paths 320 about the field lines 316 depends linearly on the strength of the field according to the well-known relationship r_{g}=mv/qB, where m, q, and v are respectively the mass, charge, and velocity of the ion, and B is the strength of the magnetic field. It is generally evident that the plasma may thus be concentrated at the edge of the wafer more strongly with a higher field strength. The field strength itself may be adjusted by using magnets having different strengths, by adjusting the number of magnets (including providing magnets on different levels), and the like. In some embodiments, the holding structure 314 for the magnets may be made of a magnetic conductor so that the field remains generally uniform even if there are gaps in the distribution of magnets around the ring 300 resulting from adjusting the number of magnets. Examples of gaps may be seen in FIG. 3A with designations 310.

The inventors have found that a suitable field for many applications provides a field strength on the order of 10 gauss near the chamber walls and a field strength less than about 1.0 gauss at the wafer edge. Thus in different embodiments, the field strength proximate the chamber walls is between 1 and 50 gauss, between 2 and 20 gauss, between 5 and 15 gauss, or between 8 and 12 gauss. Similarly, in different embodiments, the field strength proximate the wafer edge is between 0.1 and 5.0 gauss, between 0.2 and 2.0 gauss, between 0.5 and 1.5 gauss, or between 0.8 and 1.2 gauss. The relative field strengths at proximate the chamber walls may be defined by factors of 5-50 times the field proximate the wafer edge, 8-20 times the field proximate the wafer edge, or approximately 10 times the field proximate the wafer edge in different embodiments.

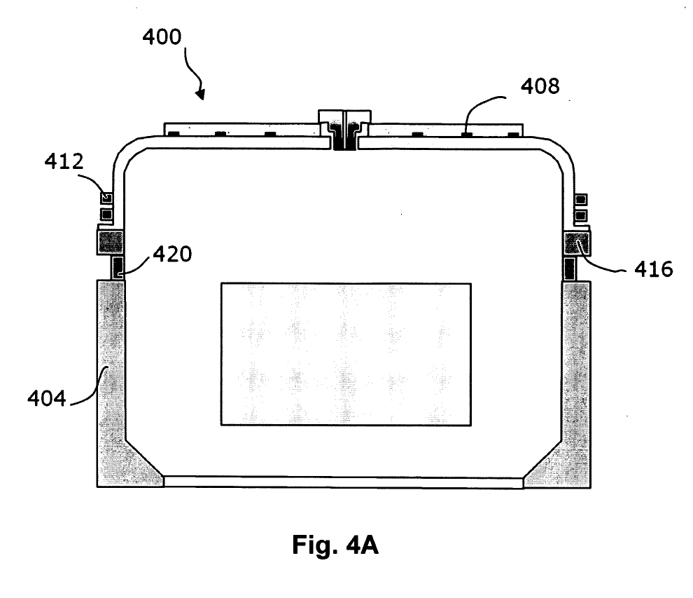

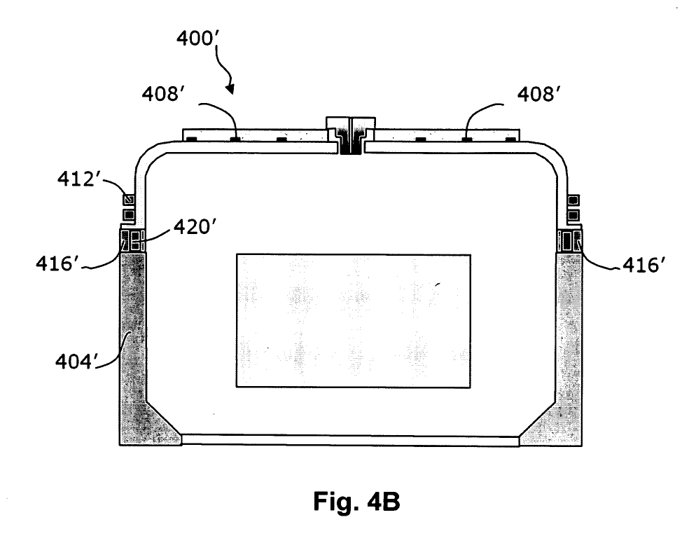

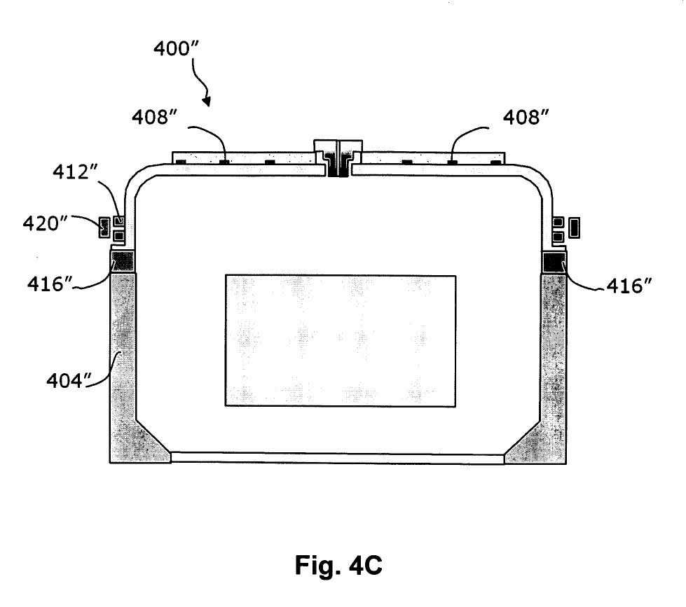

As previously noted, the magnetic confinement ring 300 may be positioned circumferentially about the chamber. The general construction of ICP systems lends itself to a number of different configurations, some of which are illustrated for specific embodiments in FIGS. 4A-4C. Each configuration shown in FIGS. 4A-4C is advantageously axisymmetric about a symmetry axis of the ICP chamber, but it will be recognized that other embodiments may provide the magnetic confinement ring 300 nonaxisymmetrically. For example, in FIG. 4A, the ICP system is denoted generally by reference number 400 and may have a configuration like that described in connection with FIG. 1. To orient the schematic illustration of FIG. 4A, the chamber walls are denoted by reference number 404, the gas ring is denoted by reference number 416, the top RF coils are denoted by reference number 408, and the gas ring is denoted by reference number 416. In the embodiment of FIG. 4A, the magnetic confinement ring 420 is provided as a spacer ring. Such an embodiment is advantageously requires no modification of parts, but has the effect of increasing the volume of the chamber.

Another embodiment is shown schematically in FIG. 4B with the ICP system denoted by reference number 400′ and having chamber walls 404′, top coil 408′, side coil 412′, and gas ring 416′. In this embodiment, the magnetic confinement ring 420′ is integrated with the gas ring 416′, which has the effect of maintaining the chamber volume but requires modifications to the gas ring 416′. A further embodiment is shown schematically in FIG. 4C with the ICP system denoted by reference number 400″ and comprising chamber walls 404″, top coil 408″, side coil 412″, and gas ring 416″. In this embodiment, the magnetic confinement ring 420″ is disposed circumferentially about the side coil 412″, which also has the effect of maintaining the chamber volume but without the need for modification of parts. In addition, this embodiment more easily permits the edge density to be tunable.

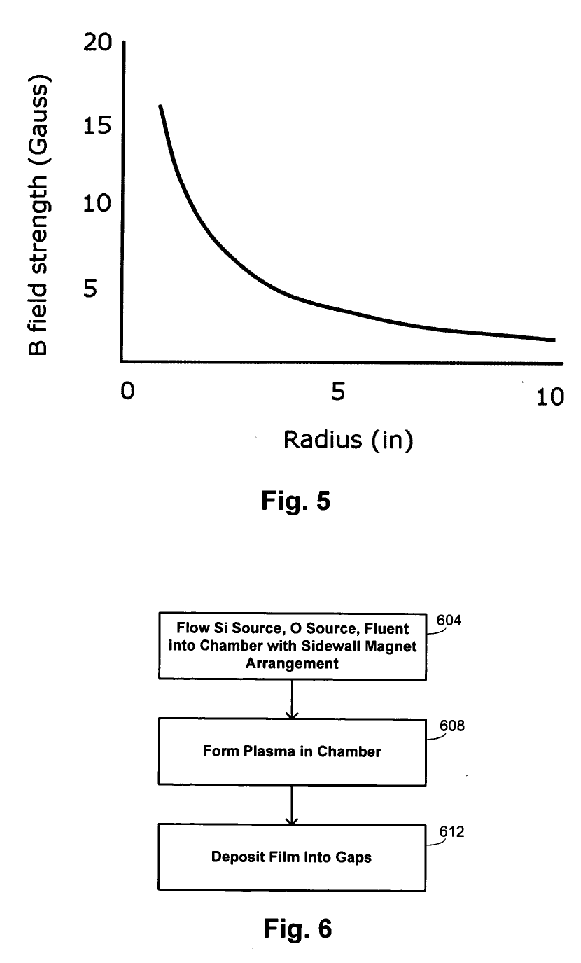

FIG. 5 provides an illustration of the field strength that may be achieved using a magnetic confinement ring according to embodiments of the invention. The results shown in FIG. 5 are for a magnetic confinement ring provided with an ICP system used in processing 200-mm-diameter wafers. For a 200-mm wafer, the edge of the wafer is near 4 inches and the chamber walls are near 8 inches. The curves show that the field strength at the edge of the wafer is about 1 gauss and is on the order of 10 gauss at the chamber walls, consistent with the values provided above. It is also apparent that the field strength is strongest in the plane of the magnetic confinement ring, decreasing in strength as expected outside that plane.

The ICP systems of the invention may thus be used for gapfill deposition processes with improved wafer uniformity. Such methods for gapfill deposition are broadly summarized with the flow diagram of FIG. 6 for deposition of a silicon oxide material over a substrate and within gaps on the substrate. At block 604, a silicon source, an oxygen source, and a fluent gas are flowed into a chamber that includes a sidewall magnet arrangement such as described above. The silicon source may comprise a silane such as monosilane SiH₄ and the oxygen source may comprise an oxygen-containing gas such as molecular oxygen O₂. Different fluent gases may be used in different embodiments, including inert gases such as Ar, Ne, and He and including H₂, or combinations thereof. Furthermore, dopants may be added to the film by including a precursor gas with the desired dopant, such as by including a flow of SiF₄ to fluorinate the film, including a flow of PH₃ to phosphorate the film, including a flow of B₂H₆ to boronate the film, including a flow of N₂ to nitrogenate the film, and the like. At block 608, a plasma is formed in the chamber, such as by forming a high-density plasma with an ion density of at least 10¹¹ ions/cm³, permitting the film to be deposited over the substrate and within the gaps at block 612.

To illustrate the effect of the magnetic confinement ring, the inventors undertook a number of experiments to quantify the uniformity by using a Langmuir probe to compare ion saturation currents at the center and at the edge of a wafer for various power inputs. The results of such comparisons are summarized in Table I, with baseline values being determined for a system without the magnetic confinement ring. The measurements were performed for a silicon oxide deposition process using He as the fluent gas on a 200-mm wafer.

TABLE I
Langmuir-Probe Comparison of Ion-Saturation Currents

| RF Power (W) | | Baseline Ion-Saturation | | Ion-Saturation Current with | |
|---|---|---|---|---|---|
| Top | Side | Current (mA) | | Magnetic Ring (mA) | |
| Coil | Coil | Center | Edge | Center | Edge |
| 4800 | 4800 | 1703 | 1531 | 1672 | 1645 |
| 2400 | 4800 | 1126 | 1025 | 1090 | 1093 |
| 10 | 4800 | 414 | 400 | 419 | 446 |
| 4800 | 4800 | 1703 | 1531 | 1672 | 1645 |
| 4800 | 2400 | 1446 | 1275 | 1387 | 1335 |
| 4800 | 0 | 1241 | 1009 | 1171 | 1043 |
| 2400 | 2400 | 858 | 769 | 822 | 806 |
| 2400 | 0 | 635 | 519 | 595 | 525 |
| 10 | 2400 | 186 | 183 | 190 | 198 |

The results clearly show that the center and edge ion-saturation currents are more consistent when the magnetic confinement ring is included, confirming that its use improves uniformity over the wafer.

Having fully described several embodiments of the present invention, many other equivalents or alternative embodiments of the present invention will be apparent to those skilled in the art. The scope of the invention should, therefore, be determined not with reference to the above description, but instead should be determined with reference to the appended claims along with their full scope of equivalents.

What is claimed is:

1. A substrate processing system comprising:
a housing defining a process chamber;
a substrate holder disposed within the process chamber and configured to support a substrate within a substrate plane during substrate processing;
a gas-delivery system configured to introduce a gas into the process chamber;
a pressure-control system for maintaining a selected pressure within the process chamber;
a high-density-plasma generating system operatively coupled with the process chamber;
a magnetic confinement ring having a plurality of magnetic dipoles disposed circumferentially around a symmetry axis orthogonal to the substrate plane and providing a magnetic field with a net dipole moment substantially nonparallel with the substrate plane; and
a controller for controlling the gas-delivery system, the pressure-control system, and the high-density-plasma generating system.

2. The substrate processing system recited in claim 1 wherein the net dipole moment is substantially orthogonal to the substrate plane.

3. The substrate processing system recited in claim 2 wherein each of the plurality of magnetic dipoles has a dipole moment that is substantially orthogonal to the substrate plane.

4. The substrate processing system recited in claim 1 wherein the plurality of magnetic dipoles comprise a plurality of permanent magnets.

5. The substrate processing system recited in claim 1 wherein the magnetic confinement ring comprises a plurality of levels that are substantially parallel to the substrate plane, the plurality of magnetic dipoles being disposed among the plurality of levels.

6. The substrate processing system recited in claim 1 wherein the magnetic confinement ring comprises a holding structure made of magnetically conductive material, the plurality of magnetic dipoles being held by the holding structure.

7. The substrate processing system recited in claim 1 wherein the magnetic confinement ring is substantially circular.

8. The substrate processing system recited in claim 1 wherein the magnetic confinement ring is disposed circumferentially around the housing.

9. The substrate processing system recited in claim 1 wherein:
the high-density-plasma generating system comprises a side RF coil disposed circumferentially around the housing; and
the magnetic confinement ring is disposed circumferentially around the side RF coil.

10. The substrate processing system recited in claim 1 wherein:
the gas-delivery system comprises a gas ring disposed circumferentially around the housing; and
the magnetic confinement ring is integrated with the gas ring.

11. The substrate processing system recited in claim 1 wherein the magnetic confinement ring is substantially axisymmetric with the symmetry axis.

12. The substrate processing system recited in claim 1 wherein the magnetic confinement ring provides a field strength at an edge of a substrate disposed on the substrate holder less than about 2 gauss.

13. The substrate processing system recited in claim 1 wherein the magnetic confinement ring provides a field strength at an edge of a substrate disposed on the substrate holder less than about 1 gauss.

14. A method for depositing a film on a substrate disposed in a substrate plane within a substrate processing chamber, the method comprising:
flowing a process gas into the substrate processing chamber;
inductively forming a plasma having an ion density greater than 10¹¹ ions/cm³ from the process gas;
generating a magnetic field with a magnetic confinement ring having a plurality of magnetic dipoles disposed circumferentially around a symmetry axis orthogonal to the substrate plane, the magnetic field having a net dipole moment substantially nonparallel with the substrate plane; and
depositing the film over the substrate with the plasma in a process that has simultaneous deposition and sputtering components.

15. The method recited in claim 14 wherein:
the substrate has a trench formed between adjacent raised surfaces; and
depositing the film over the substrate with the plasma comprises depositing the film within the trench.

16. The method recited in claim 14 wherein the process gas comprises a silicon source, an oxygen source, and a fluent gas.

17. The method recited in claim 14 wherein the net dipole moment is substantially orthogonal to the substrate plane.

18. The method recited in claim 14 wherein the magnetic confinement ring is substantially axisymmetric with the symmetry axis.

19. The method recited in claim 14 wherein the magnetic confinement ring provides a field strength at an edge of the substrate less than about 2 gauss.

20. The method recited in claim 14 wherein the magnetic confinement ring provides a field strength at an edge of the substrate less than about 1 gauss.
